(19) United States
(12) Patent Application Publication
(10) Pub. No.: US 2025/0087968 A1
(43) Pub. Date: Mar. 13, 2025

(54) ULTRA-SMALL LASER OSCILLATOR UTILIZING SELF-RESONANCE IN A PATTERNED INDIRECT BANDGAP MATERIAL

(71) Applicant: Korea University Research and Business Foundation, Seoul (KR)

(72) Inventors: Su Hyun GONG, Seoul (KR); Jung Hyun SUNG, Seoul (KR)

(73) Assignee: Korea University Research and Business Foundation, Seoul (KR)

(21) Appl. No.: 18/826,692

(22) Filed: Sep. 6, 2024

(30) Foreign Application Priority Data
Sep. 12, 2023 (KR) 10-2023-0121277

(51) Int. Cl. H01S 5/10

(52) U.S. Cl. CPC H01S 5/1075

(57) ABSTRACT

The present disclosure relates to an ultra-small laser oscillator utilizing self-resonance in a pattered indirect bandgap material. The ultra-small laser oscillator using self-resonance according to an embodiment may include a substrate; and a resonator that is formed of transition metal dichalcogenides (TMDs) on the substrate, supports a whispering gallery mode (WGM), and performs lasing in a form of a continuous wave at room temperature.

### CROSS-REFERENCE TO RELATED APPLICATION

This application claims priority to Korean Patent Application No. 10-2023-0121277, filed on Sep. 12, 2023, in the Korean Intellectual Property Office, the disclosure of which is incorporated herein by reference.

### ACKNOWLEDGEMENT

This project (result) is the result of the Samsung Future Technology Promotion Project carried out with support from the Samsung Future Technology Promotion Foundation. “Research project title: Study of light trapping and strong interaction phenomenon using single atomic layer semiconductor.”

### BACKGROUND OF THE DISCLOSURE

### Field of the Disclosure

The present disclosure relates to the laser oscillation in the materials with an indirect bandgap, and more particularly, to an ultra-small laser oscillator utilizing self-resonance of a patterned indirect bandgap material.

### Description of the Related Art

Conventional semiconductor lasers are composed of a semiconductor material and an external resonator, with lasing action achieved through the optical gain of this system.

Small semiconductor lasers that can be integrated on chips are essential for a wide range of optical applications, including optical computing, communication, and sensing. These lasers leverage numerous background technologies for their development and commercialization. They operate based on the light emission principle of semiconductor devices, making advancements in semiconductor technology crucial for enhancing their performance.

The development of high-performance semiconductor devices involves several critical technologies, including the growth of semiconductor materials, integrating with a high-quality optical cavity, and patterning techniques. Growth of high-quality semiconductor gain materials is particularly important because it is essential for achieving lasing action and reducing lasing threshold. Optimizing the optical design of small lasers is also vital. This involves refining the optical cavity structure for efficient light confinement in a gain medium. Using optical simulation tools to model and optimize various optical designs and layouts improves the efficiency and optical performance of these lasers.

In actual laser applications, only direct bandgap materials have been utilized due to the general belief that achieving lasing action in indirect bandgap materials is nearly impossible. This is because electrons and holes in the indirect bandgap of these materials cannot directly interact with photons without phonon-mediated processes. Meanwhile, the development of light sources based on silicon (Si) and germanium (Ge) materials has been highly desirable due to their compatibility with CMOS technology. Despite extensive research over recent decades, using indirect bandgap materials like Si and Ge as light sources has been limited. The lasing action of bulk crystalline Si or Ge has only been demonstrated through Raman scattering processes, which do not involve carrier recombination in the indirect bandgap.

There remains a theoretical debate on whether indirect bandgaps can provide sufficient optical gain for lasing, contingent on conditions like very low temperatures or extremely high-quality factor cavities.

This project (result) is the result of the Samsung Future Technology Promotion Project carried out with support from the Samsung Future Technology Promotion Foundation. “Research project title: Study of light trapping and strong interaction phenomenon using single atomic layer semiconductor”.

### RELATED ART DOCUMENTS

### Patent Documents

(Patent Document 1) Korean Patent No. 10-1914274 “UNIDIRECTIONAL OSCILLATION MICRO-DISK”
(Patent Document 2) Korean Patent No. 10-0640071 “MICRO-DISK LASER WITH UNIDIRECTIONAL OSCILLATION CHARACTERISTICS”

### SUMMARY OF THE DISCLOSURE

Therefore, the present disclosure has been made in view of the above problems, and it is an object of the present disclosure to provide laser oscillation of an indirect semiconductor that has never been implemented before. This is achieved by utilizing van der Waals layered semiconductor, which has a large refractive index at visible wavelengths.

It is another object of the present disclosure to reduce the volume of a laser system itself as a laser is oscillated at the self-resonance in a pattered material.

It is still another object of the present disclosure to oscillate a laser with only a very thin resonator having a thickness of 100 nm or less.

It is yet another object of the present disclosure to use a laser using a van der Waals material which can be easily transferred on another substrate or device.

In accordance with one aspect of the present disclosure, provided is an ultra-small laser oscillator using self-resonance; and a resonator that is formed of transition metal dichalcogenides (TMDs) on the substrate, is formed an internal cavity structure possessing a whispering gallery mode (WGM), and performs lasing in a form of a continuous wave at room temperature.

The transition metal dichalcogenides (TMDs) multilayers according to one embodiment may have indirect bandgap characteristics.

The resonator according to one embodiment may have at least one of a disk-shaped, square, polygonal, and oval-shaped structures to possess the whispering gallery mode (WGM).

The resonator according to one embodiment may include at least one of molybdenum disulfide (MoS₂), tungsten disulfide (WS₂), molybdenum diselenide (MoSe₂), tungsten diselenide (WSe₂), and molybdenum ditelluride (MoTe₂).

The resonator according to one embodiment may have a thickness of 100 nm or less.

The optical confinement factor of the resonator according to one embodiment may be calculated as a ratio of a gain volume to a cavity mode volume, and may be formed within 0.89.

A rate equation by the resonator according to one embodiment may be calculated by Equation 1.

$$\frac{dN}{dt} = \frac{η P}{ℏ ω {V}_{a}} - \frac{( 1 - {β}_{0} ) N}{{τ}_{sp}} ( {n}_{q} + 1 ) - \frac{F {β}_{0} N}{{τ}_{sp}} ( {n}_{q} + 1 ) - {υ}_{g} gS - \frac{N}{{τ}_{nonrad}} \qquad [ Equation 1 ]$$

$$\frac{dS}{dt} = Γ \frac{f {β}_{0} N}{{τ}_{sp}} ( {n}_{q} + 1 ) {Γυ}_{g} gS - \frac{S}{{τ}_{p}}$$

$$\frac{{dn}_{q}}{dt} = \frac{( 1 - {β}_{0} ) N}{{τ}_{sp} K} ( {n}_{q} + 1 ) + \frac{F {β}_{0} N}{{τ}_{sp} K} ( {n}_{q} + 1 ) + \frac{{υ}_{g} gS}{K} - \frac{{n}_{q} - {n}_{q 0}}{{τ}_{q}}$$

In Equation 1, N represents a carrier density, S represents a photon density of a lasing mode, n_{q} represents a phonon occupancy number, τ_{q} represents a lifetime of phonons in thermodynamic equilibrium, n_{q0} represents a lifetime of phonon occupancy number, n_{q} represents Bose-einstein distribution, and n_{q0}=1/(exp ( [symbol] ω_{q}/k_{B} T)−1).

The optical confinement factor Γ of the rate equation according to one embodiment may be calculated by Equation 2.

$$Γ = \frac{\int {ε}_{{WS}_{2}} {\vert E \vert}^{2} {dV}_{{WS}_{2}}}{\int ε {\vert E \vert}^{2} dV} \qquad [ Equation 2 ]$$

In Equation 2, ε represents a dielectric constant, and E represents an electric field.

The SE factor of whispering gallery mode (WGM) by the resonator according to one embodiment may be calculated by Equation 3.

$$β = \frac{F {β}_{0}}{[ 1 + ( F - 1 ) {β}_{0} ]} \qquad [ Equation 3 ]$$

In Equation 3, β₀ represents an SE factor without a Purcell factor(f).

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a diagram explaining an ultra-small laser oscillator using self-resonance according to an embodiment;

FIG. 2A shows a schematic diagram of the structure of a device, which is a multilayer WS₂ disk of a glass substrate;

FIG. 2B is a diagram illustrating resonators of various sizes;

FIG. 2C shows the spectral range of the red box;

FIG. 2D shows the cross-sectional electric field distribution profile of the WGM showing light densely confined in a 50 nm thick WS₂ disk;

FIG. 2E shows the electric field distribution profiles for different WGM mode numbers;

FIGS. 2F and 2G show various calculated WGM spectra as a function of the diameter and thickness of a disk;

FIG. 3A shows a schematic diagram of an electrical band diagram for multilayer WS₂, showing possible optical variations in direct and indirect bandgaps;

FIG. 3B shows an emission spectrum from multilayered WS₂;

As shown in FIG. 3C, an emission image at wavelengths of a lasing peak measured above a threshold also shows close agreement with the expected mode distribution of WGMs;

FIG. 3D shows a normalized spectrum with increasing pumping power in the spectral range of the red box in FIG. 2C;

FIG. 3E shows spectra measured at different pumping powers;

FIG. 3F represents the log scale of peak intensity of WGM versus pumping power;

FIG. 4A shows the calculation results for photon density as a function of pumping power density;

FIG. 4B shows the calculated phonon occupancy number as a function of pumping power;

FIG. 4C measures a shift in peak wavelength with increasing pumping power (left y-axis) and shows an expected redshift based on calculated phonon density as a function of pumping power (right y-axis);

FIG. 4D is a diagram showing a lasing peak shift as a function of pumping power measured with high spectral resolution;

FIG. 4E is a diagram showing the linewidth of a WGM peak as a function of pumping power;

FIG. 4F is a diagram showing WGM lasing peaks (purple), ASE peaks (pink), and SE polarization indirect bandgaps (green);

FIG. 5A shows a schematic diagram of the far-field interference measurements for emission scattered from the opposite edge of a WS₂ disk;

FIGS. 5B and 5C are diagrams showing far-field radiation patterns as a function of wavelength measured above thresholds; and

FIGS. 5E and 5F are diagrams showing the second-order correlation function g(2)(t) for the ASE (e) and lasing (f) systems.

### DETAILED DESCRIPTION OF THE DISCLOSURE

Specific structural and functional descriptions of embodiments according to the concept of the present disclosure disclosed herein are merely illustrative for the purpose of explaining the embodiments according to the concept of the present disclosure. Furthermore, the embodiments according to the concept of the present disclosure can be implemented in various forms and the present disclosure is not limited to the embodiments described herein.

The embodiments according to the concept of the present disclosure may be implemented in various forms as various modifications may be made. The embodiments will be described in detail herein with reference to the drawings. However, it should be understood that the present disclosure is not limited to the embodiments according to the concept of the present disclosure, but includes changes, equivalents, or alternatives falling within the spirit and scope of the present disclosure.

It should be understood that, although the terms first, second, third etc. may be used herein to describe various elements, these elements should not be limited by these terms. These terms are only used to distinguish one element from another element. For example, a first element may be termed a second element and a second element may be termed a first element without departing from the teachings of the present disclosure.

It should be understood that when an element is referred to as being “connected to” or “coupled to” another element, the element may be directly connected or coupled to the other element or intervening elements may be present. In contrast, when an element is referred to as being “directly connected to” or “directly coupled to” another element, there are no intervening elements present. Other words used to describe the relationship between elements or layers should be interpreted in a like fashion (e.g., “between,” versus “directly between,” “adjacent,” versus “directly adjacent,” etc.).

The terms used in the present specification are used to explain a specific exemplary embodiment and not to limit the present inventive concept. Thus, the expression of singularity in the present specification includes the expression of plurality unless clearly specified otherwise in context. Also, terms such as “include” or “comprise” should be construed as denoting that a certain characteristic, number, step, operation, constituent element, component or a combination thereof exists and not as excluding the existence of or a possibility of an addition of one or more other characteristics, numbers, steps, operations, constituent elements, components or combinations thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, preferred embodiments of the present disclosure will be described in detail with reference to the accompanying drawings. However, the scope of the present disclosure is not limited by these embodiments. Like reference numerals in the drawings denote like elements.

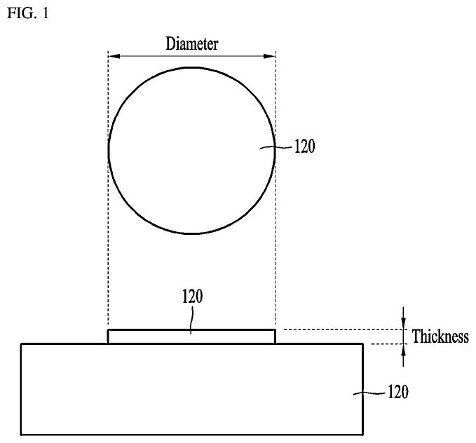

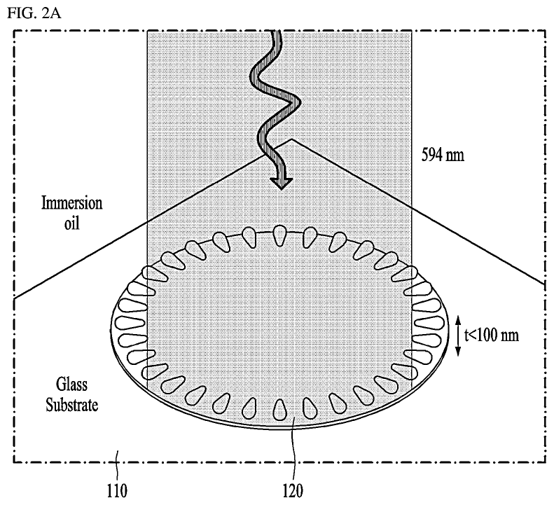

FIG. 1 is a diagram explaining an ultra-small laser oscillator 100 using self-resonance according to an embodiment.

The ultra-small laser oscillator 100 according to one embodiment includes a substrate 110 and a resonator 120 that performs lasing in the form of a continuous wave at room temperature on the substrate.

The substrate may be implemented with glass or SiO₂, and the resonator 120 may be formed with transition metal dichalcogenides (TMDs) on the substrate 110. In addition, the resonator 120 may be formed with an internal cavity structure possessing a whispering gallery mode (WGM). Through this structure, the resonator 120 may perform lasing in the form of a continuous wave at room temperature.

The transition metal dichalcogenides (TMDs) according to one embodiment have indirect bandgap characteristics and may be implemented in various types as a material group made up of transition metal disulfides.

For example, the transition metal dichalcogenides (TMDs) according to one embodiment may include at least one of molybdenum disulfide (MoS₂), tungsten disulfide (WS₂), molybdenum diselenide (MoSe₂), tungsten diselenide (WSe₂), and molybdenum ditelluride (MoTe₂).

MoS₂, known as molybdenum disulfide, is one of the best-studied TMDC materials. MoS₂ has an indirect bandgap structure and may be used in a variety of applications as a semiconductor material.

WS₂ is another well-known TMDC material. WS₂ also has an indirect bandgap structure and, as a semiconductor material, may be used in optoelectronic devices, solar cells, and optical sensors.

MoSe₂ has a similar structure to MoS₂ and has optical and electronic properties as a semiconductor material. WSe₂ has a similar structure to WS₂, and as a semiconductor material, may be used in optoelectronic devices, nanoelectronics, and optical applications.

MoTe₂ is one of TMDC materials with an indirect bandgap structure and may be applied to optoelectronic devices, transparent electronic devices, etc.

The examples above are some of the TMDC materials, more TMDC materials are being studied, and various materials with indirect bandgap characteristics may be used as resonators.

The resonator according to one embodiment may have at least one of a disk-shaped, square, polygonal, and oval-shaped structures to possess the whispering gallery mode (WGM).

The whispering gallery mode (WGM) is a phenomenon that occurs in optical or electromagnetic wave resonators, and is similar in that sound waves travel along a curved wall and are clearly heard on the other side.

WGM occurs when a light wave propagates in an optical space or structure, and the wave may propagate in a ring shape along a curved or spherical boundary such as an optical fiber, microsphere, or crack.

In the present disclosure, the WGM occurs in the resonator 120, which is formed of at least one of a disk-shaped, square, polygonal, and oval-shaped structures, and total internal reflection occurs at the boundary of the resonator 120, effectively trapping light and forming a travel path. Accordingly, light waves are concentrated into a localized mode and have a high quality factor (Q-factor).

The resonator 120 according to one embodiment is characterized by having a thickness of 100 nm or less by being implemented with an indirect bandgap type TMDC material.

In addition, the optical confinement factor of the resonator 120 is calculated as the ratio of the gain volume to the cavity mode volume, and may be formed ˜0.89.

The rate equation by the resonator 120 may be calculated through the carrier density, the photon density of a lasing mode, and the phonon occupancy number.

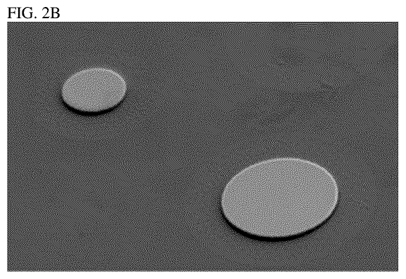

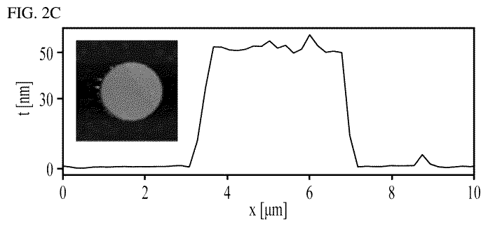

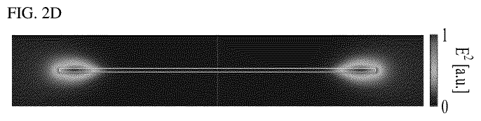

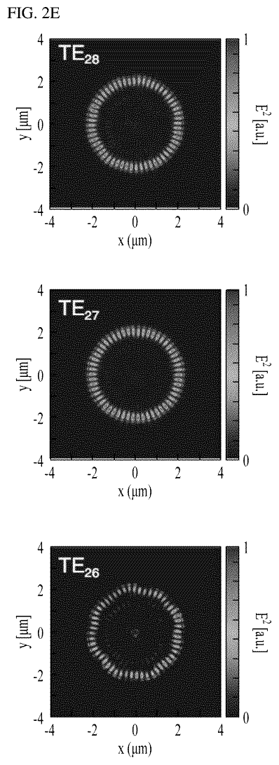

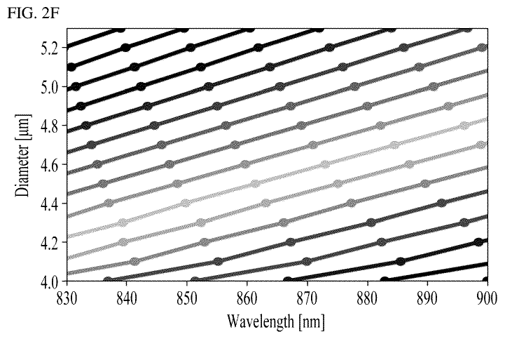

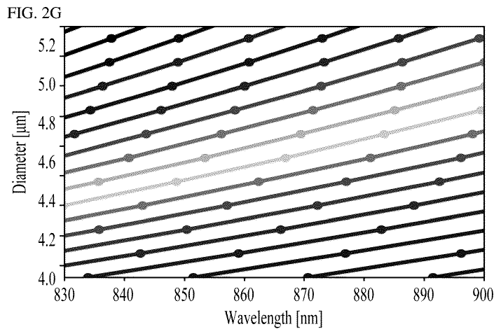

FIG. 2A shows a schematic diagram of the structure of the device, which is a multilayer WS₂ disk of a glass substrate.

The resonator according to one embodiment may be implemented in the form of an exciton laser based on various TMD materials.

For example, a laser may be manufactured by combining an external cavity structure with an optical resonance mode and a TMD monolayer.

Hereinafter, for convenience of explanation, in this specification, the present disclosure is described in which the glass substrate and resonator are implemented in the form of a multilayer WS₂ disk.

Continuous waveform light was successfully realized at room temperature using a WS₂ monolayer.

The gain volume of monolayer-based devices is greatly limited due to atomically thin nature (<1 nm), and the optical mode volume of the integrated cavity is limited by optical diffraction.

In addition, TMD monolayers exhibit a bandgap transition at high carrier density due to bandgap renormalization, which may lead to lasing failure. Using multilayer TMDs in lasing devices may increase the gain volume, but this has attracted much less research attention because multilayer TMDs have an indirect bandgap.

The present disclosure reports lasing operation in indirect bandgap transition in a multilayer WS₂ disk without the presence of external optical direction structure. Due to the high refractive index (n≈4) of WS₂, an ultra-thin WS₂ disk (thickness of ˜50 nm) may support WGM at wavelengths of indirect bandgap transition (˜880 nm).

Since the WS₂ disk used as a resonator provides both cavity mode and gain, the high optical confinement factor (ratio of gain volume to cavity mode volume) may be advantageous in reducing a lasing threshold.

In addition, WS₂ multilayer provides a highly efficient three-level system for the population inversion of carrier distribution, and provides efficient carrier pumping through exciton transition followed by fast carrier relaxation into an indirect bandgap with a slow decay time. As a result, the present disclosure may exhibit an indirect transition lasing phenomenon from a WS₂ disk at room temperature.

In conventional laser devices with TMD monolayers, the selection of cavity materials for fabricated microcavity structures and the quality factor of the fabricated microcavity structures are limited because the gain of most TMD materials is at visible wavelengths.

The resonator in the present disclosure uses an ultra-thin WS₂ layer as a means to confine light within a WS₂ layer.

The use of multilayer TMDs as passive nanophotonic structures, such as MIE resonators, photonic crystals, or flat lenses, has recently attracted interest because the high refractive index thereof may control light even in very thin TMD layers.

FIG. 2B shows resonators of various sizes and shows a scanning electron microscope image of the manufactured WS₂ disk. The scale bar was set at 3 μm.

FIG. 2C shows the spectral range of the red box.

In particular, FIG. 2C shows the thickness (˜50 nm) of a WS₂ disk measured using an atomic force microscope (AFM).

In addition, FIG. 2D shows the cross-sectional electric field distribution profile of the WGM showing light highly confined in a 50 nm thick WS₂ disk. The scale bar was set at 5 μm.

FIG. 2E shows the electric field distribution profiles for different WGM mode numbers.

FIGS. 2F and 2G show various calculated WGM spectra as a function of the diameter and thickness of a disk.

In particular, FIG. 2F shows the calculated WGM distribution for various diameters with a thickness of 50 nm, and FIG. 2G represents various thicknesses with a diameter of 4.5 μm.

In the present disclosure, it was discovered that disk-shaped WS₂ flakes have WGM in the ultrathin thickness limit (tens of nanometers). FIG. 2E shows the electric field distribution profiles for different WGM mode numbers. The cross-sectional electric field distribution profile of WGM shown in FIG. 2D shows light densely confined in a 50 nm thick WS₂ disk. FIGS. 2F and 2G show the calculated WGM spectrum, which may be variously expressed as a function of the diameter and thickness of a disk.

The quality factor due to radiation loss of WGM may be estimated to be over 400 when material loss is neglected.

To experimentally prove the structure of the ultra-small laser oscillator using self-resonance according to an embodiment, WS₂ disks of various sizes may be manufactured as shown in FIG. 2B, and emission may be investigated by C. W. optical pumping.

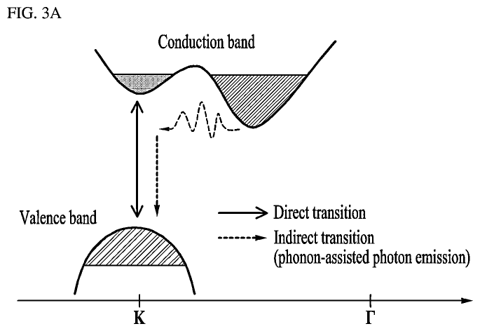

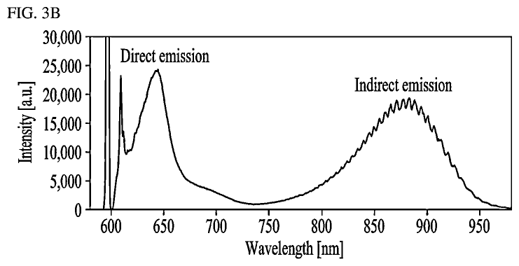

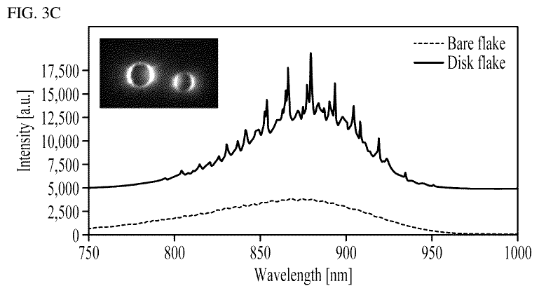

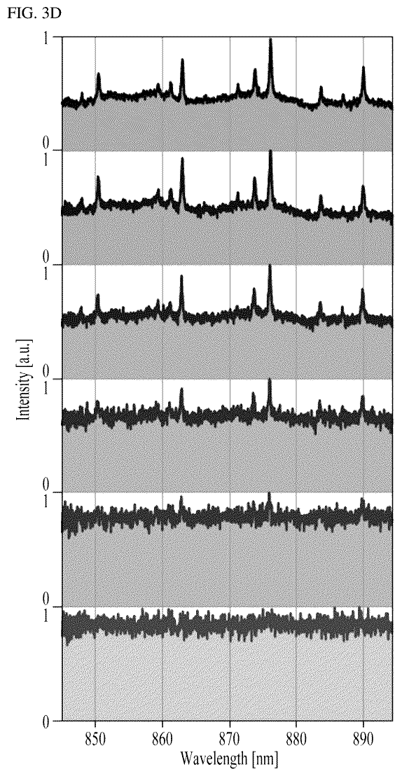

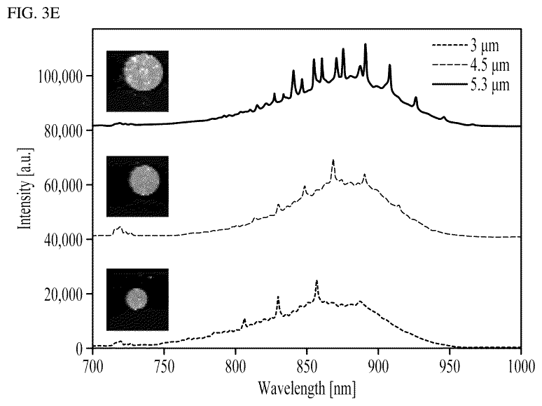

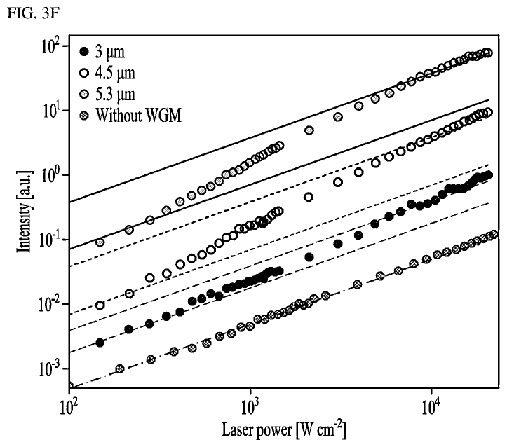

FIG. 3A shows a schematic diagram of an electrical band diagram for multilayer WS₂, showing possible optical variations in direct and indirect bandgaps, and FIG. 3B shows an emission spectrum from multilayered WS₂. In addition, in FIG. 3C, an emission image at wavelengths of a lasing peak measured above a threshold also shows close agreement with the expected mode distribution of WGMs.

FIG. 3B shows the emission spectrum from multilayered WS₂ and two peaks at ˜630 and ˜880 nm corresponding to emission from direct and indirect bands, respectively. In the present disclosure, when pumping the manufactured WS₂ disk, it was found that the emission spectrum was accompanied by a very distinctive sharp peak at the top of the wide indirect-bandgap emission (FIG. 3C).

As shown in FIG. 3E, since the free spectral range (FSR) of a mode was closely correlated with a disk diameter, the measured peaks could be attributed to WGM. The spectra in FIG. 3E were measured at different pumping powers. The overall redshift of the background indirect band GAP emission may be attributed to the laser-induced heating effect.

In the case of exciton emission, no WGM peak was observed because reabsorption of photons near the exciton resonance is too strong to form WGM. The experimentally observed FSR was higher than the value calculated for the bulk WS₂ refractive index, suggesting that the thin WS₂ layer used in the present disclosure had a lower refractive index.

As shown in FIG. 3C, an emission image at wavelengths of a lasing peak measured above a threshold also shows close agreement with the expected mode distribution of WGMs.

In addition, FIG. 3D shows a normalized spectrum with increasing pumping power in the spectral range of the red box in FIG. 2C, and FIG. 3E shows spectra measured at different pumping powers. In addition, FIG. 3F represents the log scale of peak intensity of WGM versus pumping power.

To clarify the nonlinear behavior of the WGM peak, the present disclosure measured a photoluminescence spectrum while changing pumping power. FIG. 3D shows a normalized spectrum with increasing pumping power in the spectral range of the red box in FIG. 2C.

At very low excitation powers, the spectrum of an indirect band is very similar to that of the patterned WS₂ layer, with barely visible WGM peaks. As pumping power increases, several prominent WGM peaks appear, and intensity increases rapidly as a function of the pumped carrier density.

The relatively high intensity of an indirect bandgap emission spectrum is due to the large pumping area of the entire disk, whereas WGM exists only at the edge of the disk.

The intensity of the WGM peak may become more dominant with local excitation at the edge of the disk.

In addition, the light collection efficiency for WGM in the experimental configuration is very low compared to the direct radiation of the background emission.

The peak intensity of WGM versus pumping power (Light-In versus Light-Out, L-L curve) may be displayed on a log scale in FIG. 3F.

This represents the transition from spontaneous emission (SE) to nonlinear amplified spontaneous emission (ASE), and finally switches to laser and shows a characteristic S-shape.

In contrast, the emission intensity without WGM shows only linear SE behavior over the entire pumping range, indicating that lasing action is occurring via WGM. All manufactured WS₂ disks (various diameters of 3.0, 4.5, and 5.3 μm) exhibit clear S-shaped lasing in the L-L curve.

To better understand the lasing process, experimental data may be fit to a theoretical model using a rate equation.

For indirect band gap transition modeling, in the present disclosure, phonon-assisted photon absorption and emission may be considered by adding the time dynamics of phonon density to the rate equation (method).

Since the emission spectrum of an indirect band is located at a lower energy than the theoretically calculated indirect bandgap energy, in the present disclosure, it may be assumed that the absorption and emission of photons may be aided by the absorption and emission of phonons, respectively.

According to the present disclosure, the rate equation by the resonator may be calculated by Equation 1.

$$\frac{dN}{dt} = \frac{η P}{ℏ ω {V}_{a}} - \frac{( 1 - {β}_{0} ) N}{{τ}_{sp}} ( {n}_{q} + 1 ) - \frac{F {β}_{0} N}{{τ}_{sp}} ( {n}_{q} + 1 ) - {υ}_{g} gS - \frac{N}{{τ}_{nonrad}} \qquad [ Equation 1 ]$$

$$\frac{dS}{dt} = Γ \frac{f {β}_{0} N}{{τ}_{sp}} ( {n}_{q} + 1 ) {Γυ}_{g} gS - \frac{S}{{τ}_{p}}$$

$$\frac{{dn}_{q}}{dt} = \frac{( 1 - {β}_{0} ) N}{{τ}_{sp} K} ( {n}_{q} + 1 ) + \frac{F {β}_{0} N}{{τ}_{sp} K} ( {n}_{q} + 1 ) + \frac{{υ}_{g} gS}{K} - \frac{{n}_{q} - {n}_{q 0}}{{τ}_{q}}$$

In Equation 1, N represents a carrier density, S represents the photon density of a lasing mode, n_{q} represents a phonon occupancy number, τ_{q} represents the lifetime of phonons in thermodynamic equilibrium, n_{q0} represents the lifetime of the phonon occupancy number, n_{q} represents Bose-einstein distribution, and n_{q0}=1/(exp ( [symbol] ω_{q})/k_{B} T)−1).

Specifically, F represents a Purcell factor, Γ represents a confinement factor, Vₐ represents an active volume, τₛₚ represents a spontaneous emission lifetime, τₚ represents a photon lifetime, τ_{nonrad} represents a nonradiative recombination lifetime, τ_{q} represents a phonon lifetime, n_{q0} represents n_{q} at thermodynamic equilibrium, K represents the phonon density of state, η represents absorption efficiency, Nₜᵣ represents a transparency density, β represents a spontaneous emission factor, a represents a absorption cross section, and v_{g} represents a group velocity.

More specifically, as the values of each parameter, the Purcell factor may be 20, the confinement factor may be 0.89, the active volume may be 1.1 μm³, the spontaneous emission lifetime may be 10 ns, the photon lifetime may be 0.19 ps, the nonradiative recombination lifetime may be 4 ns, the phonon lifetime may be 50 ps, n_{q} at thermodynamic equilibrium may be 0.2294, the phonon density of state may be 6×10²⁴, the absorption efficiency may be 48%, the transparency density may be 1.51×10¹⁸ cm⁻³, the spontaneous emission factor may be 0.39, the absorption cross section may be 1.0×10⁻¹⁵ cm², and the group velocity may be 1.2×10⁸ m/s.

In addition, the optical confinement factor Γ of the rate equation may be calculated by Equation 2.

$$Γ = \frac{\int {ε}_{{WS}_{2}} {\vert E \vert}^{2} {dV}_{{WS}_{2}}}{\int ε {\vert E \vert}^{2} dV} \qquad [ Equation 2 ]$$

In Equation 2, ε represents a dielectric constant, and E represents an electric field.

In addition, the SE factor of whispering gallery mode (WGM) by the resonator may be calculated by Equation 3. In Equation 3, β₀ may be interpreted as an SE factor without a Purcell factor (f).

$$β = \frac{F {β}_{0}}{[ 1 + ( F - 1 ) {β}_{0} ]} \qquad [ Equation 3 ]$$

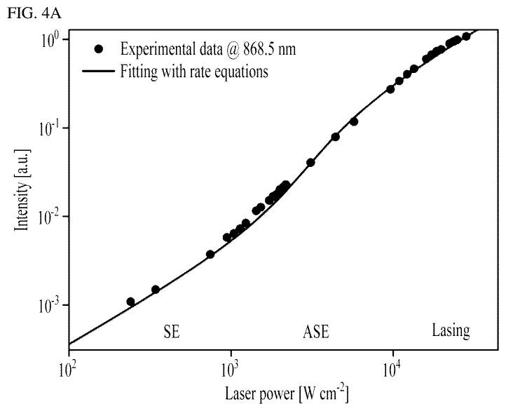

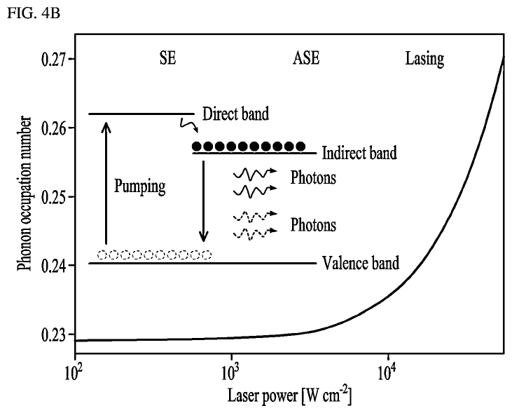

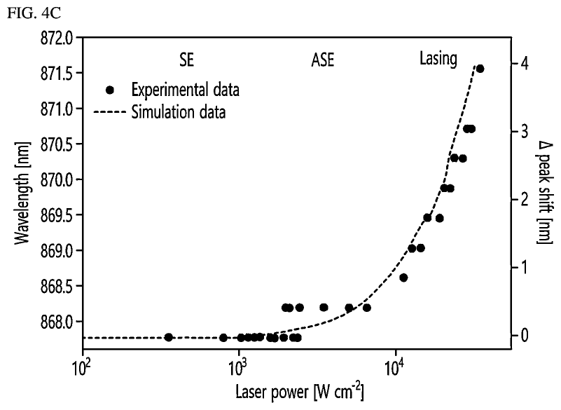

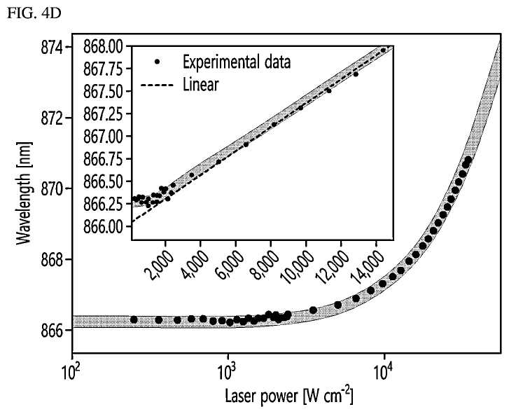

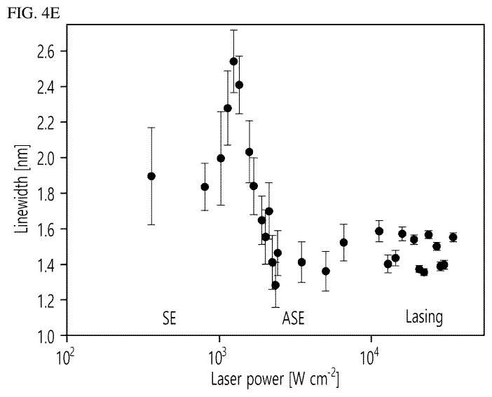

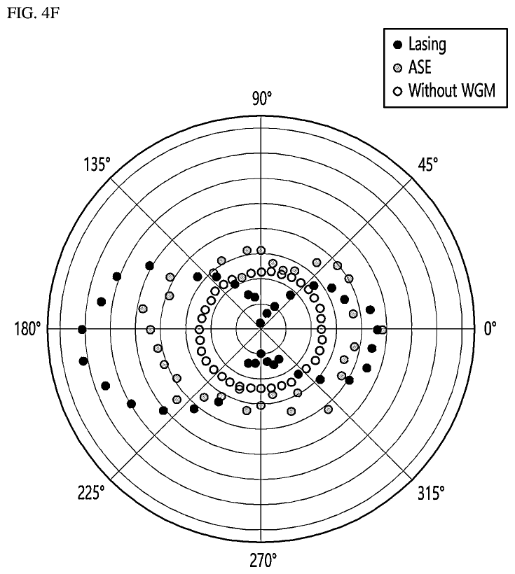

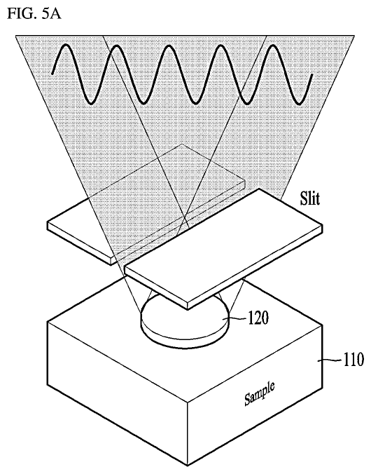

FIG. 4A shows the calculation results for photon density as a function of pumping power density. In addition, FIG. 4B shows the calculated phonon occupancy number as a function of pumping power.

As shown by the solid line in FIG. 4A, the calculation results of photon density as a function of pumping power density successfully reproduce the measured L-L curve. The fitting result of a threshold is 1.25 kW cm⁻².

In addition, as shown in FIG. 4B, according to the rate equation, photons and phonon density (or phonon occupancy number, nq) increase rapidly above a critical pumping power due to stimulated emission of photons accompanied by phonon emission.

The characteristics of threshold behavior of n_{q} may be observed experimentally.

FIG. 4C measures a shift in peak wavelength with increasing pumping power (left y-axis) and shows an expected redshift based on calculated phonon density as a function of pumping power (right y-axis). FIG. 4C shows the laser peak wavelength at which pumping power increases, showing an intense and sustained redshift above the threshold.

Redshift of an optical peak occurs when the refractive index of a material increases at a heated crystal temperature. Accordingly, in the present disclosure, the observed redshift is due to the threshold behavior of n_{q}, a rapid increase in the threshold above n_{q} increases the crystal temperature and causes subsequent redshift of the WGM.

The calculated n_{q} (FIG. 4B) and the estimated redshift of the peak for high n_{q} (FIG. 4C, right Y axis) as a function of pumping power also closely match the experimental redshift data. The redshift of the lasing peak measured with high spectral resolution is presented in FIG. 4D.

FIG. 4D is a diagram showing a lasing peak shift as a function of pumping power measured with high spectral resolution.

The linear-linear graph in FIG. 4D shows the threshold behavior of redshift more clearly with a kink in the curve near the lasing threshold. These results are in excellent agreement with the calculated n_{q} and are independent of pumping-induced thermal effects.

The threshold behavior in the redshift of the lasing peak has not been observed in conventional lasing devices and may therefore be an important signature of indirect transfer lasing.

Then, other lasing characteristics of WS₂ disk were investigated.

FIG. 4E is a diagram showing the linewidth of a WGM peak as a function of pumping power.

Obvious linewidth-narrowing of WGM was observed near the threshold (FIG. 4E). The intrinsic linewidth of the WGM measured below the threshold corresponds to a quality (Q) factor of 400. The excellent agreement with the calculated Q-factor due to radiative loss indicates that reduction in Q-factor due to intrinsic material loss is negligible. The wavelength of indirect bandgap transition is indicated.

It was also observed that the linewidth was narrowed by a factor of 2 through high spectral resolution measurements. The polarization of the laser peak was also investigated (FIG. 4F).

FIG. 4F is a diagram showing WGM lasing peaks (purple), ASE peaks (pink), and SE polarization indirect bandgaps (green).

In the present disclosure, a high linear polarization degree of ˜0.9 was observed for the laser peak, distinguishing it from SE that does not bind to WGM, which exhibits unpolarized emission. The direction of linear polarization was tangent to the disk, which may be interpreted as the result of a WGM-mediated lasing action such as transverse electric current (TE).

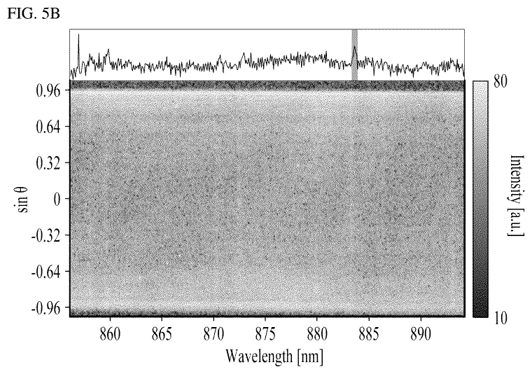

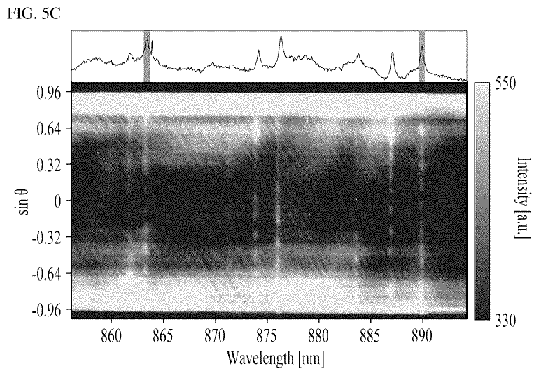

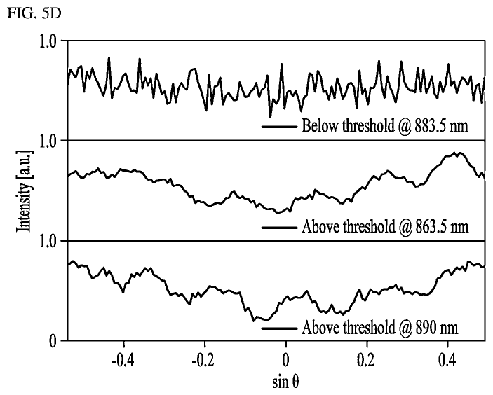

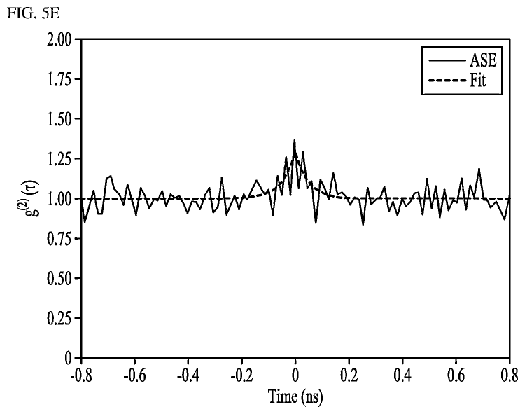

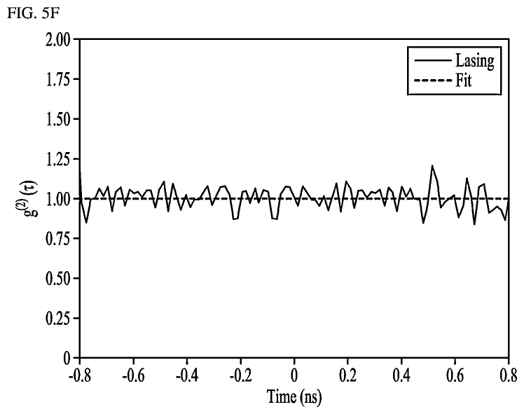

FIG. 5A shows a schematic diagram of the far-field interference measurements for emission scattered from the opposite edge of a WS₂ disk.

In the present disclosure, the far-field interference as a function of wavelength was imaged using a Fourier plane spectrometer setup to confirm the consistency of laser emission. Scattered WGM emission may be collected from two opposite edges of a selected region of the disk.

FIGS. 5B and 5C are diagrams showing far-field radiation patterns as a function of wavelength measured above thresholds.

That is, FIGS. 5B and 5C represent the angular distributions of distributed light below and above the threshold of the laser, respectively. No visible distinguishable oscillation pattern was observed at low pumping power. However, beyond the threshold of increasing pumping power, interference patterns along the angular direction were observed only at the wavelength of the WGM peak.

FIG. 5D is a diagram showing the cross-sectional plot of the angular distribution of light measured below and above a threshold at a WGM wavelength.

In addition, in the present disclosure, it was confirmed that the spacing of fringes varied at the wavelength of the WGM peak (see FIG. 5D). In addition, these interference fringes were not visible below the critical power where light was seen at a single edge or no lasing occurred. Accordingly, the existence of the interference pattern proves that light becomes coherent due to lasing emission. Accordingly, the presence of interference patterns demonstrates that the scattered lasing emissions from opposing edges of the disk are coherent with each other.

Characterizing photon statistics by measuring the second-order correlation function g(2)(t) may provide more direct demonstration of the lasing phenomenon. In the present disclosure, a high-resolution lattice was used to spectrally filter a single WGM peak, ensuring that the temporal coherence of emission was greater than the temporal resolution of a single photon-counting detector.

FIGS. 5E and 5F are diagrams showing the second-order correlation function g(2)(t) for the ASE (e) and lasing (f) systems.

At the pumping power of the ASE system, emission is g(2)(0)=1.3±0.14 (FIG. 5E), which means that photons are clustered together.

When the pumping power is lasing power, g(2)(0)=1, which shows a coherent emission situation in which photons are not emitted in clusters but are emitted randomly (FIG. 5F).

In general, the indirect bandgap transition of WS₂ may also be expected to exhibit low optical transition rates.

In fact, the experimentally observed carrier decay times in the direct and indirect bands (˜50 ps and >7 ns, respectively) indicate that the indirect band transition may have a transition rate that is two orders of magnitude smaller than the direct bandgap transition.

Despite these severe limitations for use in optical emission devices, lasing from a WS₂ disk was possible as a continuous waveform. Such continuous lasing oscillation at room temperature is difficult to achieve even with a TMD monolayer.

The present disclosure offers several possible explanations. First, the electrical bandgap structure of multilayer WS₂ may provide a very efficient three-stage gain system.

As shown in FIG. 4B, carrier pumping from a valence band directly to a conduction band may be efficiently achieved using a pumping laser with photon energy near exciton resonance.

As a result, the population inversion in the indirect conduction band may be easily achieved at low pumping levels.

In addition, for phonon emission dominant optical transitions at indirect bandgap, positive optical gain may be achieved without the population inversion as described in the rate equation.

This is because phonon absorption and stimulated emission depend on the number of phonon occupancies in the system, so SE of the phonon occurs regardless of the presence of the phonon.

Accordingly, for low phonon densities, the probability of photons being emitted by phonon emission may be higher than the probability of photons being absorbed by phonon absorption, which may indicate positive gain (that is, negative absorption).

In addition, the WS₂ disk, used as an example of a resonator, has a much higher optical confinement factor (˜0.89) than a conventional laser device with a TMD monolayer because the WS₂ disk provides both cavity mode and gain (<0.01). The confinement factor is an important factor for a laser device in reducing the laser threshold of a device.

That is, the confinement factor of the WS₂ disk structure, which is two orders of magnitude higher than that of the conventional structure, compensates for the low material gain of an indirect bandgap, which is expected to be two orders of magnitude lower than that of a direct bandgap, which results in a similar modal gain.

In conclusion, the present disclosure shows unprecedented lasing behavior in indirect bandgap transition. The minimum size of the WS₂ disk laser proven in previous research related to the present disclosure was ˜0.58λ₀³ (that is, size-to-wavelength (λ₀) ratio 0.58).

Through this, the ultra-small laser oscillator with self-resonances according to the present disclosure has the advantage of van der Waals materials and facilitates integration with other systems through a dry transfer method. In addition, room temperature C. W. lasing operation may suggest excellent potential for practical applications due to the low lasing threshold.

According to one embodiment, by utilizing a pattered TMD semiconductors with a high refractive index and indirect bandgap transition, laser oscillation of an indirect semiconductor that has never been implemented before can be obtained.

According to one embodiment, as the laser is oscillated using self-resonance, the volume of the laser system itself can be reduced.

According to one embodiment, a laser can be oscillated with only a single, very thin resonator with a thickness of 100 nm or less.

According to one embodiment, lasers using van der Waals materials can be easily combined and used with other substrates or devices.

Although the present disclosure has been described with reference to limited embodiments and drawings, it should be understood by those skilled in the art that various changes and modifications may be made therein. For example, the described techniques may be performed in a different order than the described methods, and/or components of the described systems, structures, devices, circuits, etc., may be combined in a manner that is different from the described method, or appropriate results may be achieved even if replaced by other components or equivalents.

Therefore, other embodiments, other examples, and equivalents to the claims are within the scope of the following claims.

What is claimed is:

1. An ultra-small laser oscillator using self-resonance, comprising:
a substrate; and
a resonator that is formed of transition metal dichalcogenides (TMDs) on the substrate, is an internal cavity structure possessing a whispering gallery mode (WGM), and performs lasing in a form of a continuous wave at room temperature.

2. The ultra-small laser oscillator according to claim 1, wherein the transition metal dichalcogenides (TMDs) have indirect bandgap characteristics.

3. The ultra-small laser oscillator according to claim 1, wherein the resonator has at least one of a disk-shaped, square, polygonal, and oval-shaped structures to possess the whispering gallery mode (WGM).

4. The ultra-small laser oscillator according to claim 1, wherein the resonator comprises at least one of molybdenum disulfide (MoS₂), tungsten disulfide (WS₂), molybdenum diselenide (MoSe₂), tungsten diselenide (WSe₂), and molybdenum ditelluride (MoTe₂).

5. The ultra-small laser oscillator according to claim 1, wherein the resonator has a thickness of 100 nm or less.

6. The ultra-small laser oscillator according to claim 1, wherein a rate equation by the resonator is calculated by Equation 1 below.
$$\frac{dN}{dt} = \frac{η P}{ℏ ω {V}_{a}} - \frac{( 1 - {β}_{0} ) N}{{τ}_{sp}} ( {n}_{q} + 1 ) - \frac{F {β}_{0} N}{{τ}_{sp}} ( {n}_{q} + 1 ) - {υ}_{g} gS - \frac{N}{{τ}_{nonrad}} \qquad [ Equation 1 ]$$
$$\frac{dS}{dt} = Γ \frac{f {β}_{0} N}{{τ}_{sp}} ( {n}_{q} + 1 ) {Γυ}_{g} gS - \frac{S}{{τ}_{p}}$$
$$\frac{{dn}_{q}}{dt} = \frac{( 1 - {β}_{0} ) N}{{τ}_{sp} K} ( {n}_{q} + 1 ) + \frac{F {β}_{0} N}{{τ}_{sp} K} ( {n}_{q} + 1 ) + \frac{{υ}_{g} gS}{K} - \frac{{n}_{q} - {n}_{q 0}}{{τ}_{q}} ,$$
wherein N represents a carrier density, S represents a photon density of a lasing mode, n_{q} represents a phonon occupancy number, F represents a Purcell factor, Γ represents a confinement factor, Vₐ represents an active volume, τₛₚ represents a spontaneous emission lifetime, τₚ represents a photon lifetime, τ_{nonrad} represents a nonradiative recombination lifetime, τ_{q} represents a phonon lifetime, n_{q0} represents n_{q} at thermodynamic equilibrium, K represents a phonon density of state, η represents absorption efficiency, Nₜᵣ represents a transparency density, β represents a spontaneous emission factor, a represents an absorption cross section, and v_{g} represents a group velocity.
